(19) United States
(12) Patent Application Publication
(10) Pub. No.: US 2010/0187680 A1
(43) Pub. Date: Jul. 29, 2010

(54) Heat radiator

(75) Inventors: Kenji Otsuka, Okazaki-shi (JP); Masaru Nakashima, Toyota-shi (JP)

Correspondence Address: OLIFF & BERRIDGE, PLC, P.O. BOX 320850, ALEXANDRIA, VA, 22320-4850, US

(73) Assignee: TOYOTA JIDOSHA KABUSHIKI KAISHA, Toyota-shi (JP)

(21) Appl. No.: 12/654,440

(22) Filed: Dec. 18, 2009

(30) Foreign Application Priority Data
Jan. 23, 2009 (JP) 2009-013557

(51) Int. Cl. H01L 23/367

(52) U.S. Cl. 257/706; 257/E23.103

(57) ABSTRACT

A radiator includes: an insulating substrate, a heating element or a semiconductor chip is mounted; and a heat sink that is provided the insulating substrate through a stress relaxation member that has a stress absorbing space, in which the heat sink dissipates heat from the semiconductor chip. The insulating substrate, the stress relaxation member, and the heat sink are braze-bonded to each other. The heat sink has: a top plate that is bonded to the stress relaxation member; and a bottom plate that is bonded to the top plate, and the top plate and the bottom plate forms a passage of coolant therebetween. A thickness proportion between the top plate and the bottom plate falls within a range of 1:3 to 1:5.

### INCORPORATION BY REFERENCE

The disclosure of Japanese Patent Application No. 2009-013557 filed on Jan. 23, 2009, including the specification, drawings and abstract is incorporated herein by reference in its entirety.

### BACKGROUND OF THE INVENTION

1. Field of Invention

The present invention relates to a heat radiator. More particularly, the present invention relates to a heat radiator having: an insulating substrate, on a topside of which a heating element or a semiconductor chip is mounted; and a heat sink provided on an underside of the insulating substrate through a stress relaxation member that has a stress absorbing space, in which the heat sink dissipates heat from the semiconductor chip.

2. Description of Related Art

Conventionally, insulated gate bipolar transistor (IGBT) semiconductor power modules use a heat radiator that efficiently dissipates heat generated by the semiconductor chip to maintain the semiconductor chip at or below a predetermined temperature.

Japanese Patent Application Publication No. 2006-294699 (JP-A-2006-294699) describes a heat radiator having: an insulating substrate, on a topside of which a semiconductor chip is mounted; and a heat sink provided on an underside of the insulating substrate through a stress relaxation member that has a stress absorbing space, and the heat sink dissipates heat from the semiconductor chip, in which the insulating substrate, the stress relaxation member, and the heat sink are braze-bonded to each other. The stress absorbing space is, for example, a through hole that is formed on the stress relaxation member.

In the heat radiator described in JP-A-2006-294699, the insulating substrate, the stress relaxation member, and the heat sink are bonded to each other by brazing. This allows heat that is generated by the semiconductor chip to be efficiently conducted to the heat sink. Under certain circumstances, the semiconductor chip generates sufficient heat to cause thermal stress in the heat radiator due to different thermal linear expansion coefficients between the insulating substrate and the heat sink. When this occurs with the heat radiator described in JP-A-2006-294699, the stress relaxation member is deformed by the effect of the stress absorbing space, thereby relaxing the thermal stress. This prevents the insulating substrate from cracking.

In the heat radiator described in JP-A-2006-294699, the insulating substrate, the stress relaxation member, and the heat sink are braze-bonded together. Generally, the process of bonding the insulating substrate, the stress relaxation member, and the heat sink together is conducted as follows: First, the insulating substrate, the stress relaxation member, and the heat sink are placed one after another in layers, and restrained by a jig. Then, an appropriate load is applied to the respective bonded faces between the insulating substrate and the stress relaxation member and between the stress relaxation member and the heat sink. Subsequently, in a vacuum or under an inert gas atmosphere that is heated to approximately 600° C., the insulating substrate, the stress relaxation member, and the heat sink are braze-bonded together, and then cooled to room temperature. As described immediately above, when the insulating substrate, the stress relaxation member, and the heat sink are braze-bonded together, the atmosphere is heated to approximately 600° C., and then cooled to room temperature after the bonding process. The insulating substrate and the heat sink have different thermal linear expansion coefficients. Therefore, at a temperature of approximately 600° C., the insulating substrate and the heat sink are bonded together through the stress relaxation member, and then cooled, which causes thermal stress due to the different thermal linear expansion coefficients between the insulating substrate and the heat sink. This thermal stress is so higher than thermal stress, which is caused between the insulating substrate and the heat sink when the semiconductor chip generates heat, that the stress relaxation member cannot relax. Thus, the thermal stress can possibly damage the insulating substrate.

### SUMMARY OF THE INVENTION

The present invention provides a heat radiator that has a simple structure to relax thermal stress that occurs during the process of bonding an insulating substrate, a stress relaxation member, and a heat sink together, thereby preventing damage the insulating substrate from being damaged.

A first aspect of the present invention is directed to a heat radiator. The heat radiator has: an insulating substrate, a heating element or a semiconductor chip is mounted; and a heat sink that is provided the insulating substrate through a stress relaxation member that has a stress absorbing space, in which the heat sink dissipates heat from the semiconductor chip. In the heat radiator, the insulating substrate, the stress relaxation member, and the heat sink are braze-bonded to each other. The heat sink has: a top plate that is bonded to the stress relaxation member; and a bottom plate that is bonded to the top plate, and the top plate and the bottom plate forms a coolant passage therebetween. A thickness proportion between the top plate and the bottom plate falls within a range of 1:3 to 1:5.

The heat radiator according to the first aspect of the present invention has a simple structure to relax thermal stress that is caused in the process of bonding the insulating substrate, the stress relaxation member, and the heat sink together, thereby to prevent the insulating substrate from being damaged.

### BRIEF DESCRIPTION OF THE DRAWINGS

The foregoing and further features and advantages of the invention will become apparent from the following description of preferred embodiments with reference to the accompanying drawings, wherein like numerals are used to represent like elements and wherein:

FIG. 1 is a sectional view that illustrates a construction of a heat radiator according to one embodiment of the present invention;

FIG. 2 is a sectional view that illustrates the details of a construction of a heat sink; and

FIG. 3 shows the relationship between the ratio of the thickness of a top plate to the thickness of a bottom plate and the stress of an insulating substrate.

### DETAILED DESCRIPTION OF EMBODIMENTS

A heat radiator according to an embodiment of the present invention will be described below with reference to the drawings. The description of the embodiment focuses on a heat radiator used in a power module, as an example. The power module supplies electric power to a motor that drives an automobile.

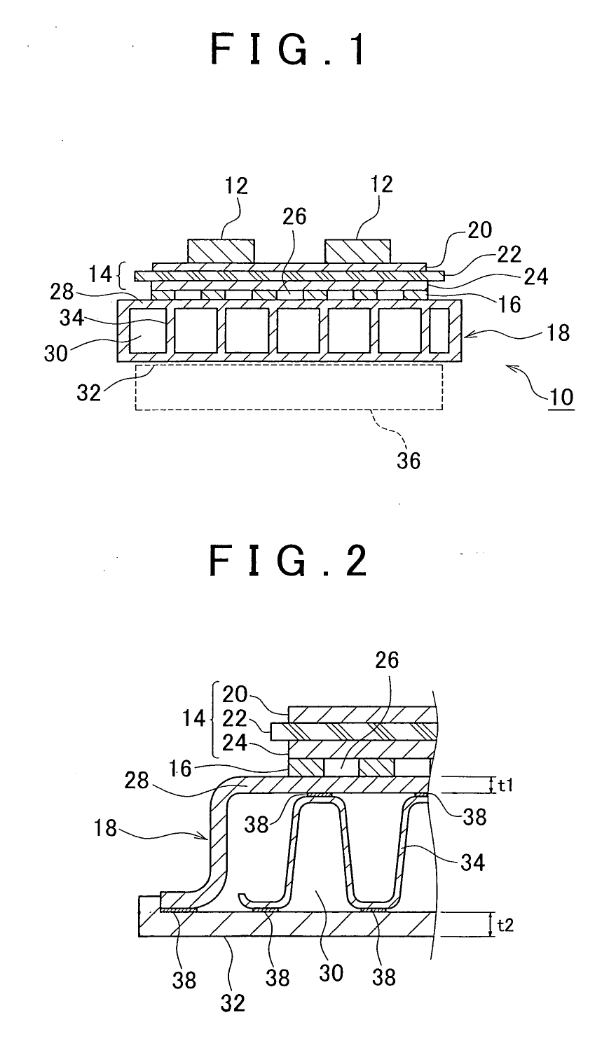

FIG. 1 is a sectional view that illustrates a construction of a heat radiator 10 according to the embodiment of the present invention. The heat radiator 10 has an insulating substrate 14 and a heat sink 18. A semiconductor chip 12 is mounted on the top face of the insulating substrate 14. The heat sink 18 is provided on the bottom face of the insulating substrate 14 through a stress relaxation member 16 that has a stress absorbing space. The insulating substrate 14, the stress relaxation member 16, and the heat sink 18 are braze-bonded to each other.

The semiconductor chip 12 may be a switching element used for an inverter or a booster converter. The semiconductor chip 12 includes an IGBT, a power transistor, a thyristor, and so forth. The switching element generates heat when it is actuated.

The insulating substrate 14 is formed of a first aluminum layer 20, a ceramic layer 22, and a second aluminum layer 24 which are stacked in the stated order.

An electric circuit is formed on the first aluminum layer 20. The semiconductor chip 12 is soldered onto and electrically connected with the electric circuit. The first aluminum layer 20 is made of aluminum, which is electrically conductive. However, the first layer 20 may be made of any material that electrically conductive, such as copper. Preferably, the first aluminum layer 20 is made of high-purity aluminum which has high electric conductivity and high deformability, and which is suitable for soldering to the semiconductor chip 12.

The ceramic layer 22 is made of ceramic that has high insulation performance, high thermal conductivity, and high mechanical strength. Aluminum oxide and aluminum nitride are examples of a suitable ceramic.

The stress relaxation member 16 is braze-bonded to the second aluminum layer 24. The second aluminum layer 24 is made of aluminum, which is also thermally conductive. However, the second layer 24 may be made of any material that has suitable thermal conductivity, such as copper. Preferably, the second aluminum layer 24 is made of high-purity aluminum which has high thermal conductivity and high deformability, and which exhibits excellent wettability with respect to a molten brazing material.

The stress relaxation member 16 has a stress absorbing space. The stress absorbing space is a through hole 26 that runs through the stress relaxation member 16 in the direction the layers are stacked. The through hole 26 may be deformed to absorb the stress. The through hole 26 is slit-shaped and disposed on the stress relaxation member 16 in a staggered arrangement. The through hole 26 is not necessarily slit-shaped, but may be a polygonal hole or a circular hole. The stress relaxation member 16 is made of aluminum that has excellent thermal conductivity. However, the stress relaxation member 16 may be made of any material with a suitable thermal conductivity, such as copper. Preferably, the stress relaxation member 16 is made of high-purity aluminum, which has high thermal conductivity and high deformability, and which exhibits suitable wettability with respect to a molten brazing material. In the description of the embodiment of the present invention, the stress absorbing space is the through hole 26 that runs through the stress relaxation member 16 in the direction that the layers are stacked. However, the present invention is not limited to this construction. Alternatively, instead of running through the stress relaxation member 16, the through hole 26 may be closed at one end.

The heat sink 18 is made of lightweight aluminum that has excellent thermal conductivity. The heat sink 18 has a top plate 28 and a bottom plate 32. The top plate 28 is bonded to the stress relaxation member 16. The bottom plate 32 is bonded to the top plate 28. The top plate 28 and the bottom plate 32 form a coolant passage 30 therebetween. A fin 34 is provided in the passage 30 such that the fin 34 connects the top plate 28 to the bottom plate 32. The fin 34 increases the contact area between the heat sink 18 and the coolant flowing through the passage 30, thereby improving heat dissipation. The coolant flowing through the passage 30 in the heat sink 18 is long life coolant (LLC) that has anticorrosion and antifreeze properties.

An electronic device 36 is provided in contact with the bottom plate 32 of the heat sink 18. A DC/DC converter and a reactor are examples of the electronic device 36. The electronic device 36 includes a heating element.

The heat radiator 10 efficiently dissipates the heat that is generated by the semiconductor chip 12 through the insulating substrate 14 and the stress relaxation member 16 to the coolant flowing through the passage 30 in the heat sink 18. The heat radiator 10 also efficiently dissipates the heat generated by the electronic device 36 to the coolant flowing through the passage 30 in the heat sink 18.

In the process of bonding the insulating substrate, the stress relaxation member, and the heat sink to each other, they are braze-bonded together at approximately 600° C., and then cooled. This causes thermal stress due to the different thermal linear expansion coefficients between the insulating substrate and the heat sink. This thermal stress is so greater than thermal stress between the insulating substrate and the heat sink induced by the heat generated by the semiconductor chip, that the stress relaxation member cannot relax. Accordingly, a heavy load can possibly be applied to the insulating substrate.

In order to solve this problem, the heat radiator 10 of the present invention includes a heat sink 18 that has a thickness proportion between the top plate 28 and the bottom plate 32 falling within the range of 1:3 to 1:5. The heat sink 18 allows thermal stress, which occurs during the process of bonding the insulating substrate 14, the stress relaxation member 16, and the heat sink 18 to each other, to be reduced, thereby preventing the insulating substrate 14 from being damaged. The construction of the heat sink 18 will be described below in detail.

FIG. 2 is a sectional view that illustrates the details of the construction of the heat sink 18. As described above, the heat sink 18 has the top plate 28, the bottom plate 32, and the fin 34. These members are bonded together by vacuum brazing. In FIG. 2, a reference numeral 38 represents a blazed area. As shown in FIG. 2, the top plate 28 and the bottom plate 32 are brazed together on their flat mating face. Brazing the top plate 28 and the bottom plate 32 together on their flat mating face enables these plates 28 and 32 to be easily and reliably bonded to each other.

The top plate 28 and the bottom plate 32 are sufficiently thin enough to ensure reduced weight and excellent thermal conductivity. To ensure sufficient durability, the top plate 28 according to the embodiment of the present invention has thickness t1 of 0.8 mm. When the thickness t1 of the top plate 28 is below 0.8 mm, the top plate 28 is easily corroded and damaged by coolant flowing through the passage 30. The thickness t1 of the top plate 28 may be greater than 0.8 mm. As long as the top plate 28 ensures reduced weight and excellent thermal conductivity, its thickness t1 may be preset in the range of 0.8 mm to 1.2 mm.

In contrast, the bottom plate 32 according to the embodiment of the present invention has thickness t2 of 4.0 mm. The reason why the thickness t2 is preset at 4.0 mm will be described below more specifically.

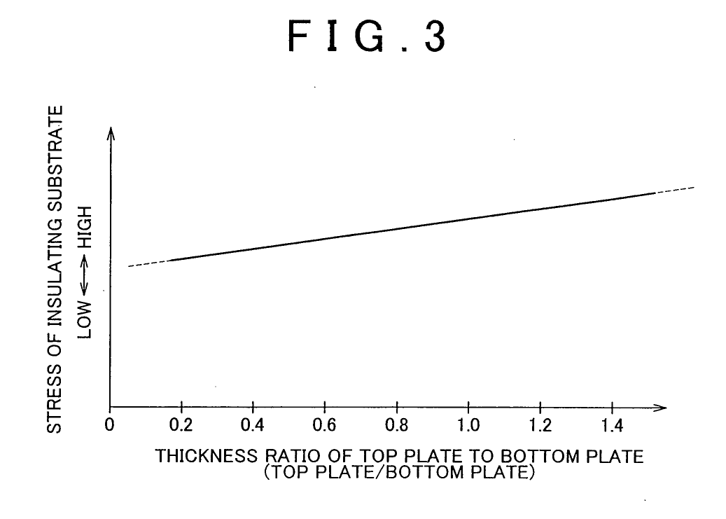

The relationship between the ratio L of the thickness of the top plate 28 to the thickness of the bottom plate 32 and the stress P of the insulating substrate 14 is described with reference to FIG. 3. The ratio L is a value obtained by dividing the thickness t1 of the top plate 28 by the thickness t2 of the bottom plate 32. The stress P occurs in the insulating substrate 14 during the process of bonding the insulating substrate 14, the stress relaxation member 16, and the heat sink 18 to each other.

Several heat sinks 18, each having a different ratio L, were experimentally bonded the insulating substrate 14, the stress relaxation member 16, and the heat sink 18. The experimental results demonstrate the tendency of the stress P to decrease with decreases in the ratio L, as shown in FIG. 3. A decrease in the stress P means that the thermal stress caused in the bonding process is reduced, and consequently the insulating substrate 14 is less likely to be damaged. In other words, as the thickness t2 of the bottom plate 32 increases relative to the thickness t1 of the top plate 28, the stress P may decrease, thereby reducing the likelihood that the insulating substrate 14 will be damaged.

However, as the thickness t2 of the bottom plate 32 increases, its weight increases, thereby increasing the weight of the heat radiator 10. In addition, as the thickness t2 of the bottom plate 32 increases, the thermal conductivity decreases. This prevents efficient dissipation of the heat generated by the electronic device 36.

Therefore, the thickness t2 of the bottom plate 32 is preset at 4.0 mm, taking relaxing the stress P as well as ensuring reduced weight and excellent thermal conductivity into account. The thickness t2 of the bottom plate 32 is not limited to 4.0 mm. The thickness t2 may be preset in a range where the stress P is relaxed, and reduced weight and excellent thermal conductivity are ensured. Preferably, the thickness t2 of the bottom plate 32 is preset at a value at which the proportion between the thickness t1 of the top plate 28 and the thickness t2 of the bottom plate 32 falls within the range of 1:3 to 1:5.

According to the embodiment of the present invention, the heat radiator 10 has such a simple structure of the heat sink 18 that the thickness proportion between the top plate 28 and the bottom plate 32 is preset in the range of 1:3 to 1:5. This structure ensures reduced weight and excellent thermal conductivity of the heat sink 18, while relaxing the thermal stress that is caused in the bonding process. Damage to the insulating substrate 14 is thus prevented.

In the above-described embodiment of the present invention, the top plate 28, the bottom plate 32, and the fin 34 of the heat sink 18 are bonded together by vacuum brazing. However, the present invention is not restricted to this configuration. Alternatively, the top plate 28, the bottom plate 32, and the fin 34 of the heat sink 18 may be braze-bonded using noncorrosive flux. In this case, the top plate 28 is coated with noncorrosive flux, which improves its durability against the coolant. This enables the thickness t1 of the top plate 28 to be preset smaller than 0.8 mm, for example, at 0.4 mm. Thereby, a further reduction in weight of the heat sink 18 and improvement in thermal conductivity of the heat sink 18 are achieved.

While the invention has been described with reference to example embodiments thereof, it is to be understood that the invention is not limited to the described embodiments or constructions. The invention is intended to cover various modifications and equivalent arrangements. In addition, while the various elements of the disclosed invention are shown in various example combinations and configurations, other combinations and configurations, including more, less or only a single element, are also within the scope of the appended claims.

What is claimed is:

1. A heat radiator comprising
an insulating substrate, a heating element or a semiconductor chip is mounted; and
a heat sink that is provided the insulating substrate through a stress relaxation member that has a stress absorbing space, the heat sink dissipating heat from the semiconductor chip,
wherein the insulating substrate, the stress relaxation member, and the heat sink are braze-bonded to each other,
the heat sink has: a top plate that is bonded to the stress relaxation member; and a bottom plate that is bonded to the top plate, the top plate and the bottom plate forming a passage of coolant therebetween, and
a thickness proportion between the top plate and the bottom plate falls within a range of 1:3 to 1:5.

2. The heat radiator according to claim 1, wherein the semiconductor chip is mounted on a top face of the insulating substrate, and
the heat sink is provided on a bottom face of the insulating substrate.

3. The heat radiator according to claim 1, wherein an electronic device that includes a heating element contacts the bottom plate.

4. The heat radiator according to claim 1, wherein the heat sink includes a fin that is provided in the coolant passage and that connects the top plate to the bottom plate, and
the fin is bonded to the top plate and to the bottom plate by vacuum brazing.

5. The heat radiator according to claim 4, wherein the top plate has thickness of 0.8 mm.

6. The heat radiator according to claim 1, wherein the heat sink includes a fin that is provided in the passage of coolant, and that connects the top plate to the bottom plate, and
the fin is bonded to the top plate and to the bottom plate, using a noncorrosive brazing material.

7. The heat radiator according to claim 6, wherein the top plate has thickness of 0.4 mm.

8. The heat radiator according to claim 1, wherein the insulating substrate is formed of a first aluminum layer, a ceramic layer, and a second aluminum layer which are stacked in the stated order.

9. The heat radiator according to claim 8, wherein the ceramic layer is made of aluminum oxide or aluminum nitride.

10. The heat radiator according to claim 1, wherein the insulating substrate is formed of a first conductive layer, a ceramic layer, and a second conductive layer which are stacked in the stated order, and
the first conductive layer and the second conductive layer are made of copper or aluminum.

11. The heat radiator according to claim 1, wherein the stress relaxation member and the heat sink are made of aluminum.

12. The heat radiator according to claim 1, wherein the stress relaxation member is made of copper.

13. The heat radiator according to claim 1, wherein the top plate has thickness of 0.8 mm to 1.2 mm.

14. The heat radiator according to claim 1, wherein the bottom plate has thickness of 4.0 mm.
